(19) United States
(12) Patent Application Publication
(10) Pub. No.: US 2018/0046206 A1
(43) Pub. Date: Feb. 15, 2018

(54) METHOD AND APPARATUS FOR CONTROLLING GAS FLOW TO A PROCESS CHAMBER

(71) Applicant: APPLIED MATERIALS, INC., Santa Clara, CA (US)

(72) Inventors: ANDREW NGUYEN, San Jose, CA (US); XUE CHANG, San Jose, CA (US)

(21) Appl. No.: 15/673,015

(22) Filed: Aug. 9, 2017

Related U.S. Application Data
(60) Provisional application No. 62/374,833, filed on Aug. 13, 2016.

(51) Int. Cl. G05D 16/20; C23C 16/455

(52) U.S. Cl. CPC G05D 16/2066; G05D 16/208; C23C 16/45561; B01D 53/92

(57) ABSTRACT

Methods and apparatus for controlling gas flow to a process chamber are disclosed herein. In some embodiments, a processing system includes a first process chamber having a first gas input; a first gas break disposed upstream of the first gas input; a first adjustable valve disposed upstream of the first gas break; and a first isolation valve disposed upstream of the first adjustable valve. The processing system may further include a second process chamber having a second gas input; a second gas break disposed upstream of the second gas input; a second adjustable valve disposed upstream of the second gas break; and a second isolation valve disposed upstream of the second adjustable valve. A shared gas source may be disposed upstream of the first isolation valve and the second isolation valve to provide one or more gases to the first process chamber and to the second process chamber.

### CROSS-REFERENCE TO RELATED APPLICATIONS

This application claims the benefit of U.S. Provisional Patent Application No. 62/374,833, filed with the United States Patent Office on Aug. 13, 2016, which is herein incorporated by reference in its entirety.

### FIELD

Embodiments of the disclosure generally relate to method and apparatus for processing a substrate.

### BACKGROUND

Processing systems having process chambers typically share processing resources such as, for example, a shared gas supply, a shared pump, etc. The shared resources reduce the cost of components of the processing system. However, the inventors have discovered that a variance exists in the gas conductance of the gas supply lines to each chamber and, thus, leads to mismatching of the chamber performance. As such, the inventors have developed an improved gas supply system to more accurately match the conductance, and thus, the process results of both chambers of the dual chamber processing system and improve uniformity of process results between substrates being processed in the different chambers.

Therefore, the inventors have provided an improved gas supply system.

### SUMMARY

Methods and apparatus for controlling gas flow to a process chamber are disclosed herein. In some embodiments, a processing system includes a first process chamber having a first gas input; a first gas break disposed upstream of the first gas input; a first adjustable valve disposed upstream of the first gas break; and a first isolation valve disposed upstream of the first adjustable valve. In some embodiments, the processing system may further include: a second process chamber having a second gas input; a second gas break disposed upstream of the second gas input; a second adjustable valve disposed upstream of the second gas break; and a second isolation valve disposed upstream of the second adjustable valve. In some embodiments, a shared gas source is disposed upstream of the first isolation valve and the second isolation valve to provide one or more gases to the first process chamber and to the second process chamber. The first process chamber and the second process chamber may be part of a dual-chamber processing system having the first process chamber and the second process chamber as adjacent process chambers having a shared wall separating respective processing volumes of the first and second process chambers.

In some embodiments, a method of controlling gas flow to a process chamber includes adjusting a first adjustable valve fluidly coupled to the process chamber upstream of a gas break to achieve a predetermined first pressure corresponding to a first flow rate at the gas break, wherein the predetermined first pressure is substantially equivalent to a reference pressure corresponding to a reference flow rate at a gas break in a reference process chamber; and processing a substrate in the process chamber while providing one or more process gases to the process chamber via the first adjustable valve.

In some embodiments, a method of controlling gas flow to a pair of process chambers, includes closing a second isolation valve fluidly coupled to a second process chamber; opening a first isolation valve fluidly coupled to a first process chamber; adjusting a first adjustable valve fluidly coupled to the first process chamber upstream of a first gas break coupled to the first process chamber to achieve a first pressure corresponding to a first flow rate at the first gas break; repeating the adjusting of the first adjustable valve until an optimal first pressure is achieved at the first gas break; closing the first isolation valve; opening the second isolation valve; adjusting a second adjustable valve fluidly coupled to the second process chamber upstream of a second gas break coupled to the second process chamber to achieve a second pressure corresponding to a second flow rate at the second gas break; repeating the adjusting of the second adjustable valve until the second pressure is substantially similar to the first pressure; opening the first isolation valve; and processing a substrate in each of the first and second process chambers while providing one or more process gases to each of the first and second process chambers via respective ones of the first and second adjustable valves.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic cross-sectional view of a process chamber in accordance with some embodiments of the present disclosure.

FIG. 2 depicts a flowchart illustrating a method of controlling gas flow to a process chamber in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure generally relate to a gas supply system. Embodiments of the inventive gas supply system advantageously improve chamber matching and deposition uniformity between multiple process chambers. Although not limiting of scope, embodiments of the present disclosure may be particularly useful when implemented in connection with a tandem processing chamber (e.g., a dual chamber or twin chamber processing system).

Embodiments of the present disclosure relate to balancing the conductance between two process chambers, such as each chamber of a twin chamber processing system, to improve the chamber matching, or side-to-side chamber matching and uniformity between the two chambers. Embodiments of the present disclosure can be used on any process chambers which need conductance adjustment. In some embodiments, conductance control can be achieved by adding a valve, such as a needle valve, next to a gas break in each chamber to add a tuning knob for conductance of gas flow into the chamber. By adjusting the needle valve, the chamber gas line conductance can be tuned, for example, to match a predetermined conductance, such as a “golden” or standard conductance determined to be a desired conductance for the process chamber.

Embodiments of the present disclosure advantageously allow adjustment to reduce or eliminate any difference in the conductance between different process chambers. In addition, embodiments of the present disclosure allow for the loosening of tolerances in the pressure drop specification for the gas breaks, which advantageously reduces the cost of manufacturing of the gas breaks.

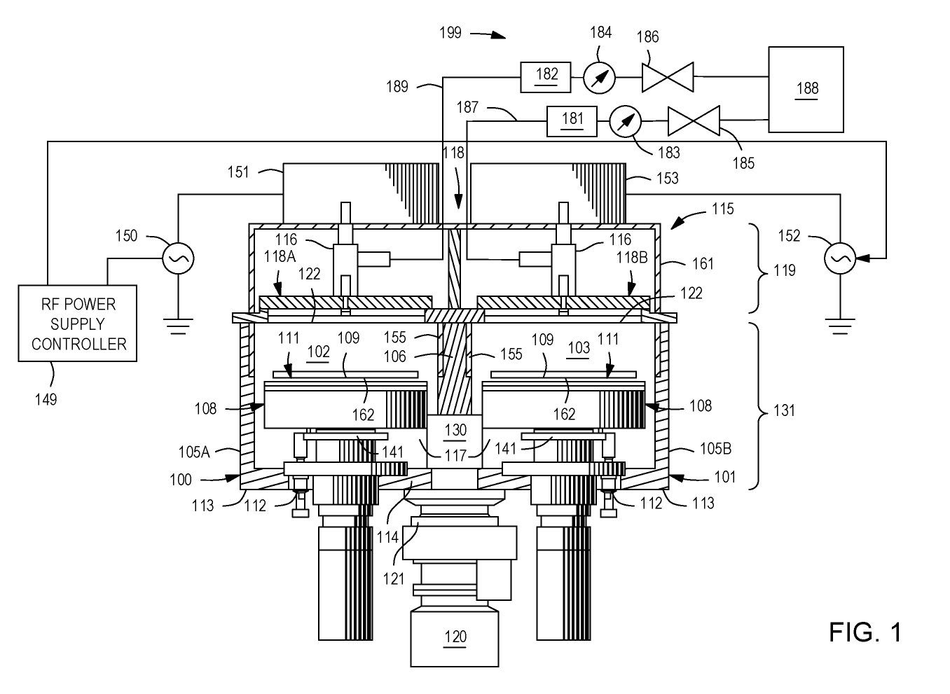

FIG. 1 illustrates a cross-sectional view of an exemplary dual chamber processing system (e.g., process chambers 100, 101) having a gas supply system 180 in accordance with some embodiments of the present disclosure. Although illustratively described in connection with a dual chamber processing system, embodiments of the present disclosure may also be used in connection with standalone process chambers. Each of the respective first and second process chambers 100, 101 may include an upper portion 119 and a lower portion 131, wherein the upper portion 119 generally includes processing regions 102, 103 and wherein the lower portion 131 generally includes a loading region 111 adjacent an aperture 109. Each of the respective first and second process chambers 100, 101 include a chamber body having sidewalls 105A,B, an interior wall 106, a bottom 113, and a lid 115 disposed on the first and second process chambers 100, 101. In some embodiments, the lid 115 is a radio frequency (RF) cover. The sidewall 105A, interior wall 106, and portion of lid 115 disposed on the first process chamber 100 define a first processing region 102. The sidewall 105B, interior wall 106 and portion of lid 115 disposed on the second process chamber 101 define a second processing region 103. The interior wall 106 is shared between the respective first and second process chambers 100, 101 and isolates the processing environment of the processing regions 102, 103 from each other. As such, the processing regions 102, 103 defined in the respective process chambers 100, 101 while process isolated, may share a common pressure, as the lower portion of interior wall 106 may allow the respective first and second process chambers 100, 101 to communicate with each other. The lower portion of interior wall 106 is defined by a central pumping plenum 117 described below.

The lid 115 may include one configuration of a gas distribution assembly 116 including a showerhead 122 configured to dispense a gas from a gas source 188 (such as a gas panel) into the respective processing regions 102, 103. The lid 115 is coupled to the gas source 188 via respective gas feedthroughs 187, 189 corresponding to processing regions 102, 103, respectively. In some embodiments, the showerhead 122 may be electrically floating. To ensure that the showerhead 122 remains electrically floating and is not grounded through the gas feedthroughs 187, 189 to the gas source 188, the gas feedthroughs 187, 189 include corresponding gas breaks 181, 182. The gas breaks 181, 182 are formed of an electrically insulative material to ensure that the showerhead 122 remains floating. The gas breaks 181, 182 may also include restrictors to substantially reduce or eliminate plasma from flowing back to the gas source 188. As such, the pressure of gas flowing into the gas breaks 181, 182 from the gas source 188 is greater than the gas pressure at the outlets of the gas breaks 181, 182.

A valve system 199 is disposed between the gas source 188 and the gas breaks 181, 182. The valve system 199 improves chamber matching by facilitating independent adjustment of the pressure in each process chamber 100, 101 to obtain a predetermined desired pressure, for example, corresponding to a pressure at a known flow rate of a different process chamber. The desired pressure values are determined based on process uniformity and yield (e.g., to maximize uniformity and yield). In some embodiments, the valve system 199 includes isolation valves 185, 186 disposed in series with corresponding adjustable valves 183, 184, respectively. Each set of valves is disposed in-line with a corresponding one of the gas breaks 181, 182 (e.g., isolation valve 186 is disposed upstream of adjustable valve 184, which is in turn disposed upstream of the gas break 182). To reduce processing discrepancies between the process chambers 100, 101, the gas breaks are designed to have substantially similar pressure drops. However, the inventors have discovered that due to manufacturing variance, no two gas breaks are identical and, even the allowable tolerance variation results in undesirable discrepancies in processing results between the process chambers 100, 101.

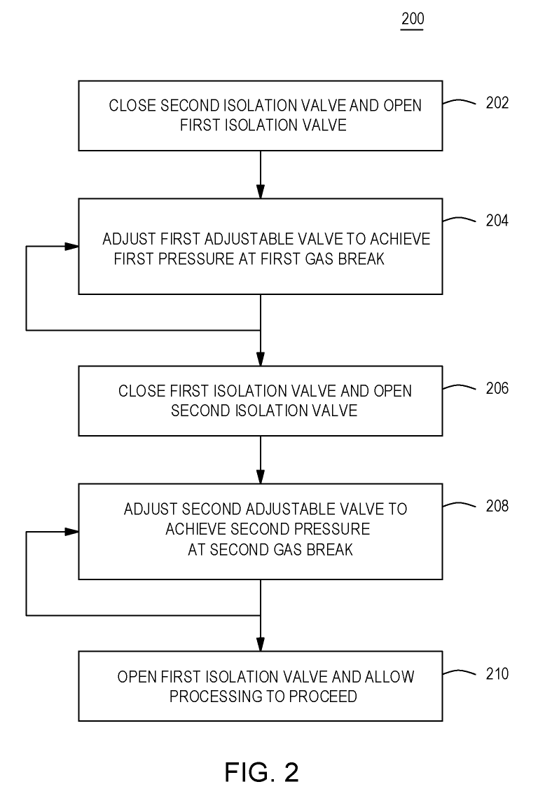

FIG. 2 depicts a method 200 of controlling gas flow to a process chamber. The method 200 is used to determine the optimal pressure values at the gas breaks 181, 182 at which chamber matching is achieved, yield is maximized, and processing uniformity between the two process chambers is maximized. The method generally begins at 202, where a second isolation valve 186 fluidly coupled to a second gas break 182 is closed and a first isolation valve 185 fluidly coupled to a first gas break 181 is opened. At 204, a first adjustable valve 183 is adjusted to achieve a first pressure corresponding to a first flow rate at the first gas break 181. 204 is optionally repeated until a desired, predetermined first pressure is achieved at the first gas break 181. The predetermined first pressure and the first flow rate are values that provide a chamber yield and processing uniformity in the process chamber 101 that more closely match a reference process chamber (such as the companion process chamber 100, or some other reference process chamber).

At 206, the first isolation valve 185 is closed and the second isolation valve 186 is opened. At 208, a second adjustable valve 184 is adjusted to achieve a second pressure corresponding to a second flow rate at the second gas break 182. 208 is optionally repeated until a desired, predetermined second pressure is achieved at the second gas break 182. The predetermined second pressure and the second flow rate are values that provide a chamber yield and processing uniformity in the process chamber 100 that more closely match a reference process chamber (such as the companion process chamber 101, or some other reference process chamber). For example, the first pressure and the second pressure may be substantially equivalent. Alternatively or in combination, the first flow rate and the second flow rate may be substantially equivalent. At 210, the first isolation valve 185 is opened and processes in both chambers 100, 101 are allowed to proceed. Although described in connection with a dual chamber processing system, the above method could also be carried out with a single process chamber in comparison to some reference process chamber to match or substantially match the pressure provided from the gas source (or another gas source) to the reference process chamber.

To achieve chamber matching, the first and second optimal pressures and flow rates are chosen to allow for substantially similar or equivalent chamber yield and processing uniformity between the process chambers 100, 101. As a result, the discrepancies between the first and second gas breaks 181, 182 due to manufacturing are irrelevant due to the advantageous adjustability of the gas pressures and flow rates at the gas breaks. As such, gas breaks having high conductance (for example at least a higher conductance than that of the valve system 199) may be advantageously used so that the valve system 199 controls the conductance of the gas flow to the chambers 100, 101.

Returning to FIG. 1, the lid 115 allows for convenient access to the chamber components such as the chamber liners 155 for example, for cleaning. In some embodiments, a cover 161 may be disposed on the lid 115 to protect components disposed in the lid 115. To help decrease chamber servicing (i.e., cleaning) time, a removable chamber liner 155 may be disposed adjacent the sidewalls 105A,B and interior wall 106. The chamber liners 155 include an aperture 162 formed in the chamber liners 155 and in communication with the aperture 109. The apertures 162 and 109 are positioned so as to enable substrates to be moved into and out of the respective process chambers 100, 101. As such, each of the apertures 109, 162 may generally be in selective communication with, for example, a substrate transfer chamber (not shown). During servicing, the lid 115 is left open so that the interior of the process chambers 100, 101 may be accessed.

When the substrate supports 108 are in a processing position, the upper portion 119 of the respective first and second process chambers 100, 101 and substrate supports 108 generally define the respective isolated processing regions 102, 103 to provide process isolation between each of the respective process chambers 100, 101. Therefore, in combination, the sidewalls 105A,B, interior wall 106, substrate support 108, and the lid 115 provide process isolation between the processing regions 102, 103.

The volume of the processing regions 102, 103 and loading regions 111 may vary with the position of the substrate support 108 relative to the lower boundary of the lid 115. In one configuration, the substrate supports 108 may be lowered below the apertures 109. In the lowered position, a substrate may be positioned on the substrate support 108 via the aperture 109. More particularly, when the substrate support 108 is lowered, the lift pin assembly 112 may lift a substrate from the upper surface of the substrate support 108. Subsequently, a robot blade (not shown) may enter into the loading region 111 and engage the substrate lifted by the lift pin assembly 112 for removal from the loading region 111. Similarly, with the substrate support 108 in a lowered positioned, substrates may be placed on the substrate support 108 for processing. Subsequently, the substrate support 108 may be vertically moved into a processing position, i.e., a position where the upper surface of the substrate support 108 is positioned proximate to the respective processing region 102, 103.

The lid 115 may have other plasma generation devices disposed adjacent to the lid 115. The upper electrode assembly 118 may be configured with RF coils coupled to first and second RF power sources 150, 152 through respective matching networks 151, 153, to inductively couple RF energy into the plasma processing regions 102, 103. An RF power supply controller 149 may be coupled to both RF power sources 150, 152 to provide an output signal for controlling, for example, a power level, phase control, and/or frequency.

The lower portion 131 of the respective first and second process chambers 100, 101 may also include a commonly shared adjacent chamber region of each chamber defined by a central pumping plenum 117 that is in fluid communication with a vacuum source 120 through a pumping valve 121. Generally, the central pumping plenum 117 includes two sections defined by the sidewalls 105A,B that are combined with an output port 130 in fluid communication with the pumping valve 121. The two sections may be formed as part of the lower portion 131 of each first and second process chambers 100, 101. While the central pumping plenum 117 may be formed integral to the lower portion 131 of the first and second process chambers 100, 101, the central pumping plenum 117 may alternatively be a separate body coupled to the lower portion 131. In a gas purge or vacuum process, the pumping valve 121 couples the vacuum source 120 to the output port 130 through mounting flange 114. Therefore, the central pumping plenum 117 is generally configured to maintain the respective process chambers 100, 101, and more particularly, the respective processing regions 102, 103, at a pressure desired for semiconductor processing while allowing for rapid removal of waste gases using the vacuum source 120.

In some embodiments, the output port 130 is positioned at a distance from the processing regions 102, 103 such as to minimize RF energy in the processing regions 102, 103, thus minimizing striking a plasma in the exhaust gases being flushed from the process chambers 100, 101. For example, the output port 130 may be positioned at a distance from the substrate supports 108 and processing regions 102, 103 that is sufficiently far to minimize RF energy within the output port 130.

In some embodiments, the upper electrode assembly 118 includes a first upper electrode assembly 118A and a second electrode assembly 118B disposed adjacent the processing regions and adapted to provide RF energy to respective processing regions 102, 103.

Although the previous description has been made with regards to a process chamber, the valve system 199 may be utilized in any process chamber in which matching of multiple chambers is desirable. The valve system may also include any combination of various types of valve to achieve the above-discussed advantages.

While the foregoing is directed to some embodiments of the present disclosure, other and further embodiments may be devised without departing from the basic scope of the disclosure.

What is claimed is:

1. A processing system, comprising:
a first process chamber having a first gas input;
a first gas break disposed upstream of the first gas input;
a first adjustable valve disposed upstream of the first gas break; and
a first isolation valve disposed upstream of the first adjustable valve.

2. The processing system of claim 1, further comprising:
a gas source disposed upstream of the first isolation valve to provide one or more gases to the first process chamber.

3. The processing system of claim 1, further comprising:
a second process chamber having a second gas input;
a second gas break disposed upstream of the second gas input;
a second adjustable valve disposed upstream of the second gas break; and
a second isolation valve disposed upstream of the second adjustable valve.

4. The processing system of claim 3, further comprising:
a shared gas source disposed upstream of the first isolation valve and the second isolation valve to provide one or more gases to the first process chamber and to the second process chamber.

5. The processing system of claim 4, wherein each of the first and second process chambers include respective showerheads configured to dispense the one or more gases from the shared gas source to respective processing volumes of the first and second processing chambers.

6. The processing system of claim 5, wherein the respective showerheads are electrically floating.

7. The processing system of claim 4, wherein the first and second gas breaks each include restrictors configured to reduce plasma from flowing from the first and second process chambers to the shared gas source.

8. The processing system of claim 3, wherein the first process chamber and the second process chamber are part of a dual-chamber processing system having the first process chamber and the second process chamber as adjacent process chambers having a shared wall separating respective processing volumes of the first and second process chambers.

9. The processing system of claim 8, wherein the dual-chamber processing system includes a central pumping plenum fluidly coupled to the respective processing volumes of the first and second process chambers.

10. The processing system of claim 3, wherein the first and second gas breaks are formed of an electrically insulative material.

11. The processing system of claim 3, wherein a fluid conductance of the first gas break is greater than that of the first adjustable valve and the first isolation valve, and wherein a fluid conductance of the second gas break is greater than that of the second adjustable valve and the second isolation valve.

12. A method of controlling gas flow to a process chamber, comprising:
adjusting a first adjustable valve fluidly coupled to the process chamber upstream of a gas break to achieve a predetermined first pressure corresponding to a first flow rate at the gas break, wherein the predetermined first pressure is substantially equivalent to a reference pressure corresponding to a reference flow rate at a gas break in a reference process chamber; and
processing a substrate in the process chamber while providing one or more process gases to the process chamber via the first adjustable valve.

13. The method of claim 12, wherein the reference process chamber is a companion process chamber coupled to the process chamber.

14. A method of controlling gas flow to a pair of process chambers, comprising:
closing a second isolation valve fluidly coupled to a second process chamber;
opening a first isolation valve fluidly coupled to a first process chamber;
adjusting a first adjustable valve fluidly coupled to the first process chamber upstream of a first gas break coupled to the first process chamber to achieve a first pressure corresponding to a first flow rate at the first gas break;
repeating the adjusting of the first adjustable valve until an optimal first pressure is achieved at the first gas break;
closing the first isolation valve;
opening the second isolation valve;
adjusting a second adjustable valve fluidly coupled to the second process chamber upstream of a second gas break coupled to the second process chamber to achieve a second pressure corresponding to a second flow rate at the second gas break;
repeating the adjusting of the second adjustable valve until the second pressure is substantially similar to the first pressure;
opening the first isolation valve; and
processing a substrate in each of the first and second process chambers while providing one or more process gases to each of the first and second process chambers via respective ones of the first and second adjustable valves.

15. The method of claim 14, wherein the one or more process gases are provided to the first and second process chambers from a shared gas source disposed upstream of the first isolation valve and the second isolation valve.

16. The method of claim 15, wherein the one or more process gases are provided to the first and second process chambers through respective showerheads configured to dispense the one or more process gases from the shared gas source to respective processing volumes of the first and second processing chambers.

17. The method of claim 15, wherein the first and second gas breaks each include restrictors configured to reduce plasma from flowing from the first and second process chambers to the shared gas source.

18. The method of claim 14, wherein the first process chamber and the second process chamber are part of a dual-chamber processing system having the first process chamber and the second process chamber as adjacent process chambers having a shared wall separating respective processing volumes of the first and second process chambers.

19. The method of claim 18, wherein the dual-chamber processing system includes a central pumping plenum fluidly coupled to the respective processing volumes of the first and second process chambers.

20. The method of claim 14, wherein a fluid conductance of the first gas break is greater than that of the first adjustable valve and the first isolation valve, and wherein a fluid conductance of the second gas break is greater than that of the second adjustable valve and the second isolation valve.
